(19) United States
(12) Patent Application Publication
(10) Pub. No.: US 2016/0173052 A1
(43) Pub. Date: Jun. 16, 2016

(54) POWER ELECTROMAGNETIC INTERFERENCE SUPPRESSION FILTER

(71) Applicant: AMAZING MICROELECTRONIC CORP., New Taipei City (TW)

(72) Inventor: TUNG-YANG CHEN, HSINCHU COUNTY (TW)

(21) Appl. No.: 14/641,538

(22) Filed: Mar. 9, 2015

(30) Foreign Application Priority Data
Dec. 16, 2014 (TW) 103143867

(51) Int. Cl. H03H 7/01

(52) U.S. Cl. CPC H03H 7/0153; H03H 7/0138

(57) ABSTRACT

A power EMI suppression filter is connected to a power feeding line of a main functional IC and other loads. The main functional IC driven by a power source supplied by the power feeding line generates an output voltage and current which are individually involved with an output voltage interference and output current interference, and a phase difference exits there-in-between. A reference providing circuit generates a first reference signal according to the output voltage interference and/or the output current interference. A primary filtering circuit calculates eigenvalues of the output voltage interference and/or the output current interference according to the first reference signal to generate a second reference signal. A secondary filtering circuit calculates eigenvalues again based on the second signal so the phase difference and amplitudes of the interferences are zero. Thus, an output voltage and current signal the load receives are DC signal without interferences.

This application claims priority for Taiwan patent application no. 103143867 filed on Dec. 16, 2014, the content of which is incorporated by reference in its entirely.

### BACKGROUND OF THE INVENTION

1. Field of the Invention

The present invention is related to on electromagnetic interference (EMI) filter, and more particularly to a power EMI suppression filter which employs a primary filtering circuit and a secondary filtering circuit to eliminate the electromagnetic interferences occurred on the power source of an IC circuit.

2. Description of the Prior Art

Since printed circuit boards (PCB) are mostly involved in transferring a plurality of various signals, wherein each signal is constructed by the superposition of many different harmonic frequency signals, each harmonic frequency signal is not only affecting the quality of the signal being transferred, but also causing a lot of interferences between one signal to another. However, the factors which affect the signals are more than these. The complicated harmonic frequency signals that are coupled to a power source of the IC are also one of the main EMI factors. What causes these coupled-harmonic frequencies are mainly generated from the inner operation of a lot of logic circuits in the main functional IC. As such, these coupled-harmonic frequency signals are becoming the main sources of the electromagnetic interferences (EMI) of electronics devices nowadays. To solve these electromagnetic interferences on the power of PCB, a variety of capacitors and filters are commonly used for now.

However, since the design concept of signal integrity (SI) and power integrity (PI) of a printed circuit board must be well simulated and associated with the electrical characteristics of the main functional IC, its circuit board thereon and a setting of boundary conditions, thus it has become quite difficult nowadays. In order to achieve the co-simulation concept, it isn't always easy for system designers to fully acquire all signal and power information of the main functional IC. Besides, since the IC designers can only handle the well signal characteristics, when it comes to the system designing part, still nothing can be well controlled by them. While for these harmonic frequency signals coupled on the power system, the system and IC designs can hardly handle them since barely very little power characteristic model of main function IC is provided. Furthermore, in order to keep the price of electronic devices nowadays more competitive, a structure of printed circuit board are downed to four-layer boards from the original six-layer boards, and from four-layer boards to two-layer boards. Under circumstances like these, it has become more and more difficult to maintain the power integrity (PI) of a shrunk printed circuit board, and the capacitors and filter used in the prior arts are apparently not applicable anymore. As such, when trying to fix the electromagnetic interferences issues occurred on the power source of the printed circuit board, many system engineers still have to use the “try and error” methods to adjust the EMI to the least, which is not only less effective but also being both time and cost consuming.

Furthermore, the electromagnetic interferences issues occurred on the power of PCB with a special harmonic frequency are generated by many different circuit block driving and sinking currents in main functional IC. Therefore, the fact that a small-signal voltage and a small-signal current are not processing synchronously is formed. Moreover, when the small-signal voltage from functional IC passes through a capacitor at the power line path, its phase difference between the small-signal voltage and the small-signal current cannot be suppressed. The worse case is that, the peak of one current signal waveform from functional IC can be aligned to the valley of transition current signal waveform bypass capacitor, which is completely 180 degree difference. Such a composition current will not only affect the electrical paths from this node to other paths (return path) on the printed circuit board to induce EMI issue, but also cause the larger voltage drop on the wires due to parasitic inductance effects. Thereby it will dramatically influent the voltage and current characteristics in a chain reaction

On account of all, it should be obvious that there is indeed an urgent need for the professionals in the field for a new EMI structure to be developed that can actively and aggressively suppress and eliminate the electromagnetic interference at the power source so as to solve the above-mentioned problems occurring in the prior design.

### SUMMARY OF THE INVENTION

In order to overcome the above-mentioned disadvantages, one major objective in accordance with the present invention is provided for a novel and creative power EMI suppression filter. By employing the novel power EMI suppression filter of the present invention, it can be utilized so as to successfully eliminate the electromagnetic interference at the power source. The power EMI suppression filter of the present invention is shunted in connection with the power and ground of the main functional IC and then connected to PCB system power/ground rail and used for eliminating the harmonic frequency waveforms and electromagnetic interferences coupled at the power source.

Another objective in accordance with the present invention is provided for a novel power EMI suppression filter, wherein by calculating one eigenvalue of at least two voltages and currents equations of the circuit, an optimum filter structure which is composed of at least one resistor, capacitor, and/or inductor can be obtained. As such, it is believed that the proposed power EMI suppression filter is so much better than the previous strategy to use the “try and error” method and is advantageous of low production cost and minimal production time as well.

And yet another objective in accordance with the present invention is provided for a novel power EMI suppression filter, which is shunted in connection to the power/ground source and the main functional IC. By employing the power EMI suppression filter of the present invention, it simply works well to eliminate the interferences having frequency range from 100 MHz up to several GHz on the power line, and still meanwhile maintain an excellent behavior of signal integrity (SI) and power integrity (PI).

For achieving the above mentioned objectives, the present invention provides a power EMI suppression filter, which is electrically connected to a power feeding line of a main functional IC and other loads. After the main functional IC is driven by a power source supplied by the power feeding line, it starts to work and generates an output voltage and an output current on this power feeding line, wherein the output voltage is involved with an output voltage interference, and the output current is involved with an output current interference, respectively. Being affected by the power harmonics interferences generated by different functional blocks in the main functional chip, a non-synchronized phase exits between the output voltage interference and the output current interference. The power EMI suppression filter of the present invention comprises a reference providing circuit, a primary filtering circuit and a secondary filtering circuit.

According to one embodiment of the present invention, the transition voltage and current of operation circuit block are electrically coupled to the power of main functional IC and generates a first reference signal according to the output voltage interference and the output current interference. The primary filtering circuit is electrically connected to the reference providing circuit in parallel and receives the first reference signal. As such, the primary filtering circuit accordingly calculates the eigenvalues of the output voltage interference and/or the output current interference and generates a second reference signal. Later, the secondary filtering circuit receives the second reference signal and calculates the eigenvalues of the output voltage interference and/or the output current interference according to the second reference signal. By calculation, the phase difference between the output voltage interference and the output current interference can be adjusted to zero, and the amplitude of the output voltage interference and the output current interference can also be adjusted to zero as well. Therefore, an output voltage and output current that the power connected to other loads are merely direct current (DC) power without any interferences or harmonics involved.

Furthermore, the present invention may further comprises at least one first adjusting circuit, second adjusting circuit, third adjusting circuit, fourth adjusting circuit or fifth adjusting circuit, which can be optionally disposed in the circuit. Since the first adjusting circuit, second adjusting circuit, third adjusting circuit, fourth adjusting circuit and fifth adjusting circuit are all composed of passive elements (for example, resistors, inductor, and/or inductors), when a controlling switch is utilized to provide a dependent voltage-current curve based on the reference signal, the calculating of eigenvalues of the output voltage interference and/or the output current interference can be derived. Therefore, a purpose of eliminating the interferences from the power feeding line of the power source is successfully accomplished.

These and other objectives of the present invention will become obvious to those of ordinary skill in the art after reading the following detailed description of preferred embodiments.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:

FIG. 1 shows a schematic drawing of the power EMI suppression filter according to one embodiment of the present invention.

FIG. 2 shows a schematic drawing of the primary filtering circuit of the power EMI suppression filter according to a first embodiment of the present invention.

FIG. 3 shows a schematic drawing of the primary filtering circuit of the power EMI suppression filter according to a second embodiment of the present invention.

FIG. 4 shows a schematic drawing of the primary filtering circuit of the power EMI suppression filter according to a third embodiment of the present invention.

FIG. 5 shows a schematic drawing of the primary filtering circuit of the power EMI suppression filter according to a fourth embodiment of the present invention.

FIG. 6 shows a schematic drawing of the secondary filtering circuit of the power EMI suppression filter according to a first embodiment of the present invention.

FIG. 7 shows a schematic drawing of the secondary filtering circuit of the power EMI suppression filter according to a second embodiment of the present invention.

FIG. 8 shows a schematic drawing of the secondary filtering circuit of the power EMI suppression filter according to a third embodiment of the present invention.

FIG. 9 shows a detailed circuit diagram of the power EMI suppression filter according to the present invention.

FIG. 10 shows a schematic drawing of the power EMI suppression filter according to another embodiment of the present invention.

FIG. 11 shows a schematic drawing of the power EMI suppression filter according to one another embodiment of the present invention.

FIG. 12 shows a schematic drawing of the power EMI suppression filter according to yet another embodiment of the present invention.

### DESCRIPTION OF THE PREFERRED EMBODIMENTS

Reference will now be made in detail to the preferred embodiments of the present invention, examples of which are illustrated in the accompanying drawings. Wherever possible, the same reference numbers are used in the drawings and the description to refer to the same or like parts.

The embodiments described below are illustrated to demonstrate the technical contents and characteristics of the present invention and to enable the persons skilled in the art to understand, make, and use the present invention. However, it shall be noticed that, it is not intended to limit the scope of the present invention. Therefore, any equivalent modification or variation according to the spirit of the present invention is to be also included within the scope of the present invention.

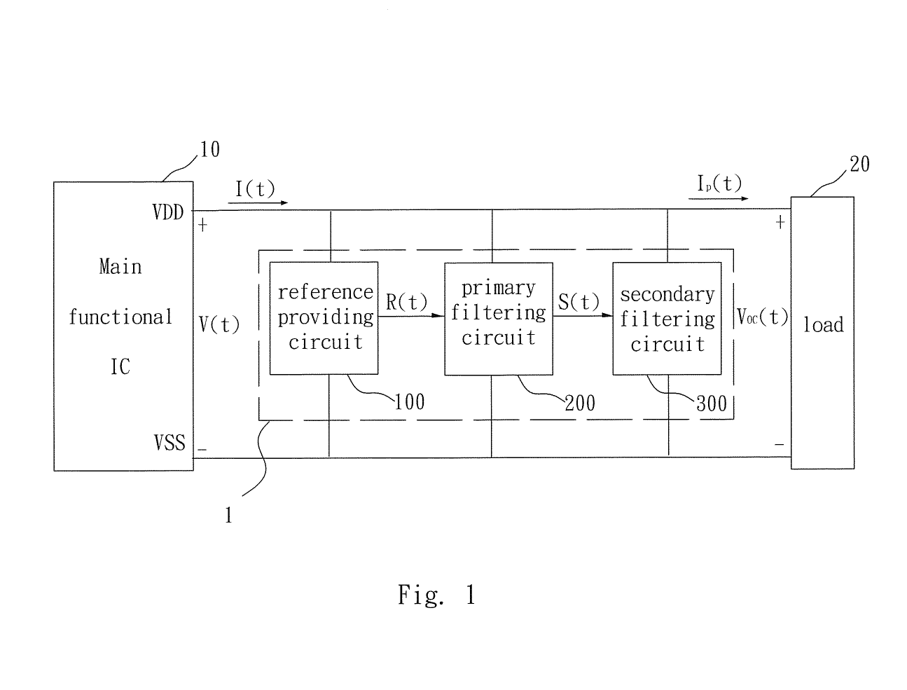

Please refer to FIG. 1, which shows a schematic drawing of the power EMI suppression filter in accordance with one embodiment of the present invention. As shown in FIG. 1, the power EMI suppression filter 1 is electrically connected to a power feeding line VDD of a main functional IC 10 and a load 20. After the main functional IC 10 is driven by a power source supplied by the power feeding line VDD, it generates an output voltage and an output current, wherein the output voltage is involved with an output voltage interference V(t), and the output current is involved with an output current interference I(t), respectively. Since the harmonic waveforms generated from the power source result in small-signals, a phase difference Φ_{c} exits between the output voltage interference V(t) and the output current interference I(t). The power EMI suppression filter 1 of the present invention is mainly designed for eliminate the phase difference Φ_{c}. As such, after being filtered by power EMI suppression filter 1, the amplitude of the output voltage interference V(t) and the output current interference I(t) can be adjusted to be minimum such that the output voltage and the output current can process synchronously. As a result, when the load 20 receives signals as the voltage signal V_{oc}(t) and the current signal Iₚ(t), they are merely direct current (DC) signals without any small-signal interferences involved.

To be more specific, the power EMI suppression filter 1 comprises a reference providing circuit 100, a primary filtering circuit 200 and a secondary filtering circuit 300. The reference providing circuit 100 is electrically coupled to the main functional IC 10 and generates a first reference signal R(t) based on the output voltage interference V(t) and/or the output current interference I(t). In other words, when the signal that the reference providing circuit 100 obtains is the output voltage interference V(t), the first reference signal R(t) it outputs is a voltage signal. Contrarily, when the signal that the reference providing circuit 100 obtains is the output current interference I(t), then the first reference signal R(t) it outputs is a current signal.

The primary filtering circuit 200 is connected in parallel to the reference providing circuit 100 to receive the first reference signal R(t). As such, the primary filtering circuit 200 can calculate the eigenvalues of the output voltage interference V(t) and/or the output current interference I(t) based on the first reference signal R(t) and generate a second reference signal S(t). Later, the secondary filtering circuit 300 receives the second reference signal S(t) and calculates the eigenvalues of the output voltage interference V(t) and/or the output current interference I(t) based on the second reference signal S(t) so as to adjust the phase difference Φ_{c} between the output voltage interference V(t) and the output current interference I(t) to be zero. At last, the signals, i.e. V_{oc}(t) and Iₚ(t) that the load 20 receives are DC signals without any interferences and harmonics involved.

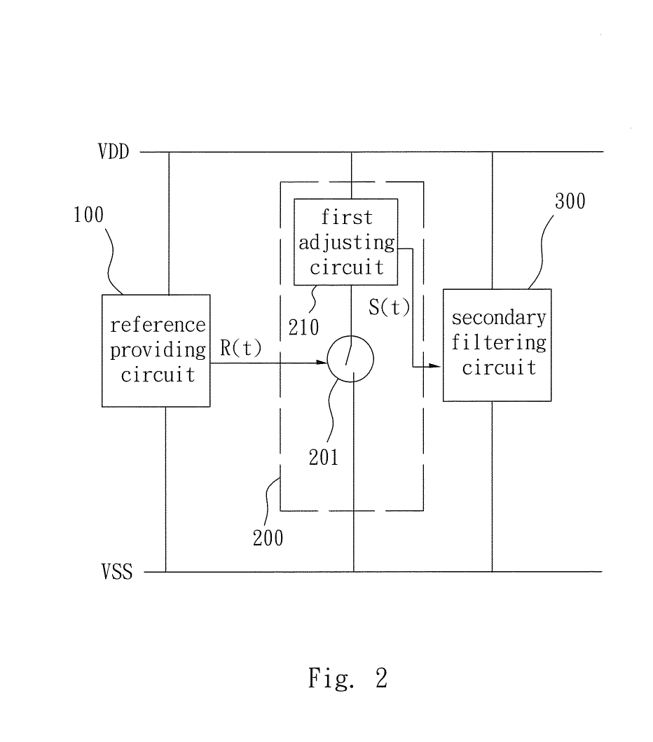

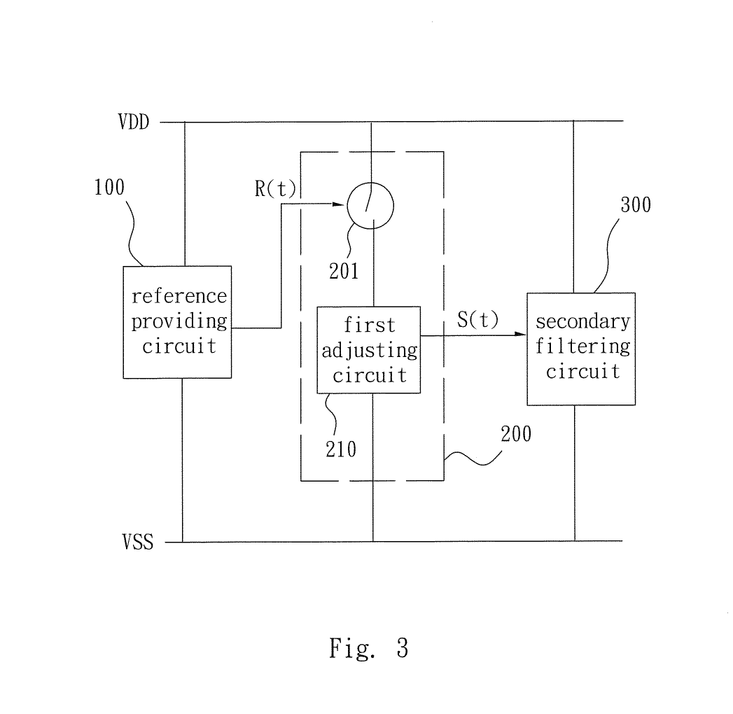

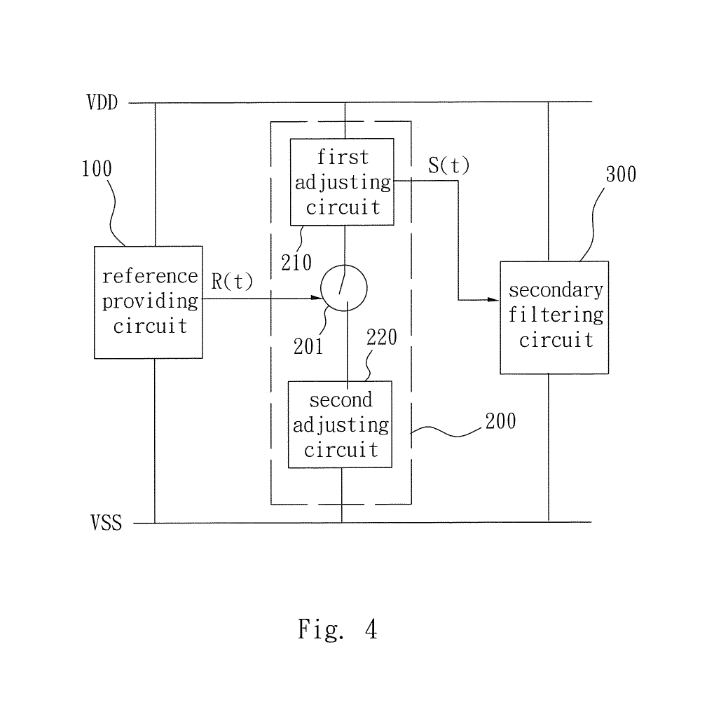

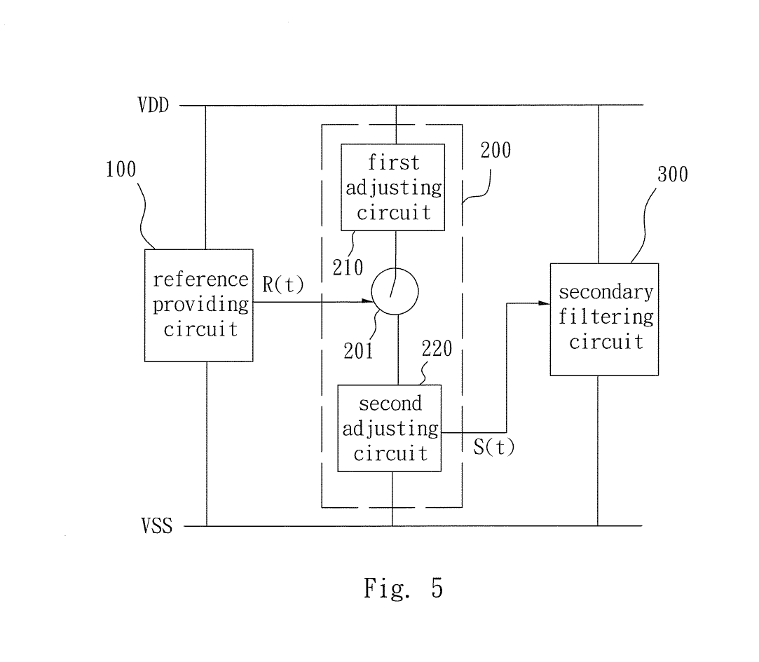

First of all, please refer to FIG. 2 to FIG. 5, which respectively shows a schematic drawing of the primary filtering circuit 200 of the power EMI suppression filter according to a first, second, third and fourth embodiment of the present invention. In general, the primary filtering circuit 200 comprises a first controlling switch 201 and at least one first adjusting circuit 210, and the first controlling switch 201 and the first adjusting circuit 210 are connected in series between the power feeding line VDD and aground line VSS, wherein the first controlling switch 201 is electrically connected to the reference providing circuit 100 to receive the first reference signal R(t). As for where the first adjusting circuit 210 is disposed, it can be disposed between the first controlling switch 201 and the power feeding line VDD as shown in FIG. 2, or between the first controlling switch 201 and the ground line VSS as shown in FIG. 3 so that the first adjusting circuit 210 can proceed with eigenvalues calculations for generating the second reference signal S(t) to the secondary filtering circuit 300. Moreover, the primary filtering circuit 200 may further comprise at least one second adjusting circuit 220, which is connected in series with the first controlling switch 201 and the first adjusting circuit 210, such that the first controlling switch 201, the first adjusting circuit 210 and the second adjusting circuit 220 are all connected in series between the power feeding line VDD and the ground line VSS as shown in FIG. 4 and FIG. 5. In the embodiments shown as FIG. 4 and FIG. 5, it is disclosed that the second reference signal S(t) can be either generated by the first adjusting circuit 210 or the second adjusting circuit 220. In other words, according to the present invention, the secondary filtering circuit 300 can be either connected to the first adjusting circuit 210 or the second adjusting circuit 220 so as to receive the reference signal it outputs and accordingly perform eigenvalues calculations.

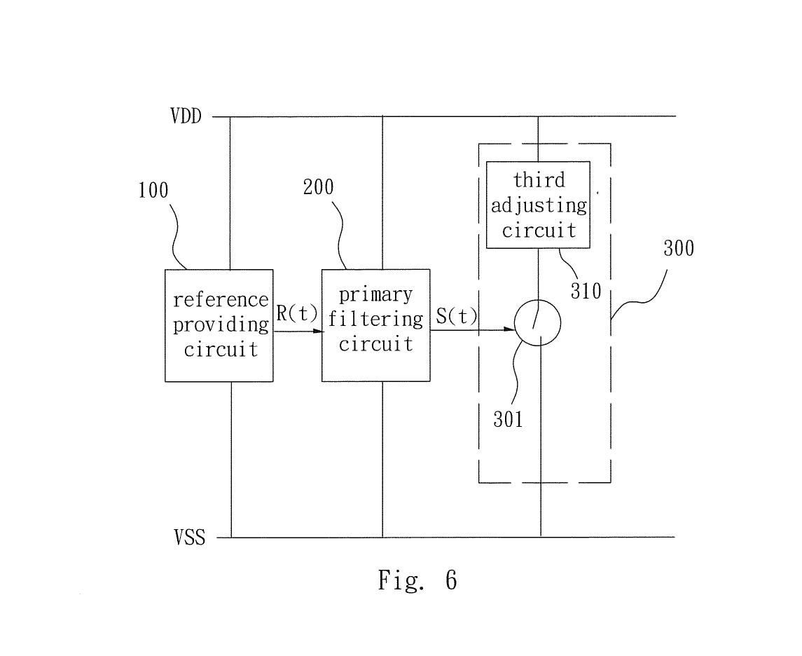

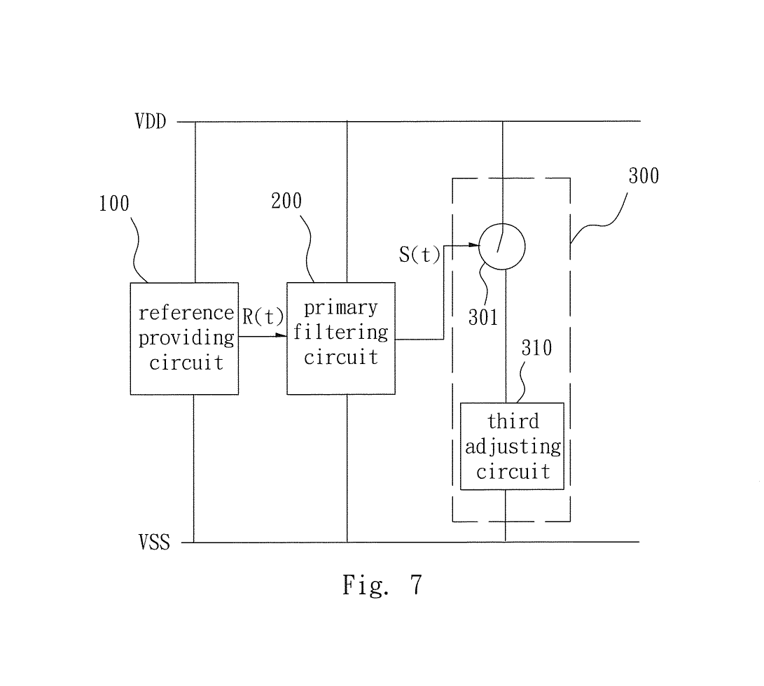

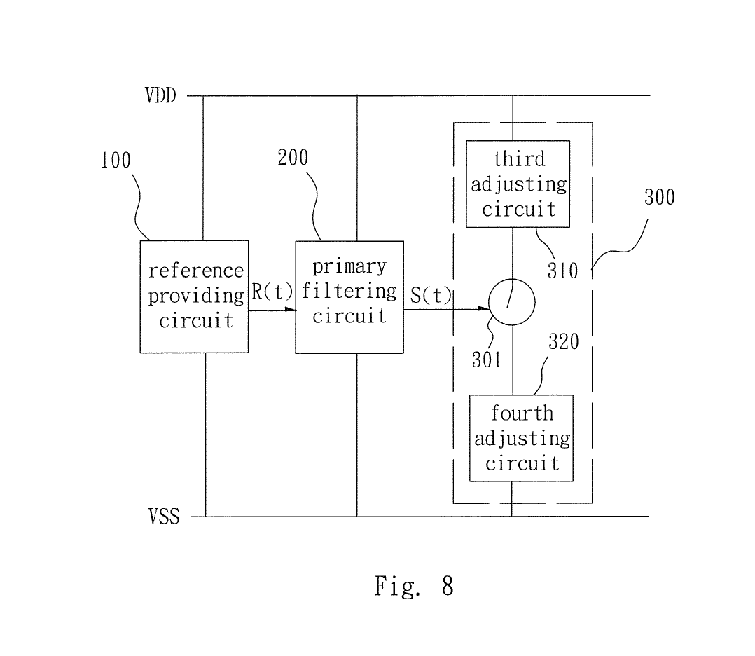

Similarly, please refer to FIG. 6 to FIG. 8, which respectively shows a schematic drawing of the secondary filtering circuit 300 of the power EMI suppression filter according to a first, second, and third embodiment of the present invention. In general, the secondary filtering circuit 300 comprises a second controlling switch 301 and at least one third adjusting circuit 310, and the second controlling switch 301 and the third adjusting circuit 310 are connected in series between the power feeding line VDD and a ground line VSS, wherein the second controlling switch 301 is electrically connected to the primary filtering circuit 200 to receive the second reference signal S(t). As for where the third adjusting circuit 310 is disposed, it can be disposed between the second controlling switch 301 and the power feeding line VDD as shown in FIG. 6, or between the second controlling switch 301 and the ground line VSS as shown in FIG. 7. Furthermore, as shown in FIG. 8, the secondary filtering circuit 300 may further comprise at least one fourth adjusting circuit 320, which is connected in series with the second controlling switch 301 and the third adjusting circuit 310, such that the second controlling switch 301, the third adjusting circuit 310 and the fourth adjusting circuit 320 are all connected in series between the power feeding line VDD and the ground line VSS.

As a result, to sum up, by optionally disposing the first adjusting circuit 210, the second adjusting circuit 220 of the primary filtering circuit 200, and the third adjusting circuit 310, and/or the fourth adjusting circuit 320 of the secondary filtering circuit 300 which are composed of passive elements (for example, resistors, inductor, and/or inductors), and a dependent voltage-current curve provided owing to the first and second controlling switch 201, 301 together with its reference signal R(t), S(t), the present invention is able to be used for showing excellent performance in eliminating those interferences generated in the power feeding line of the power source. The detailed descriptions of how the power EMI suppression filter of the present invention works to eliminate interferences are discussed below.

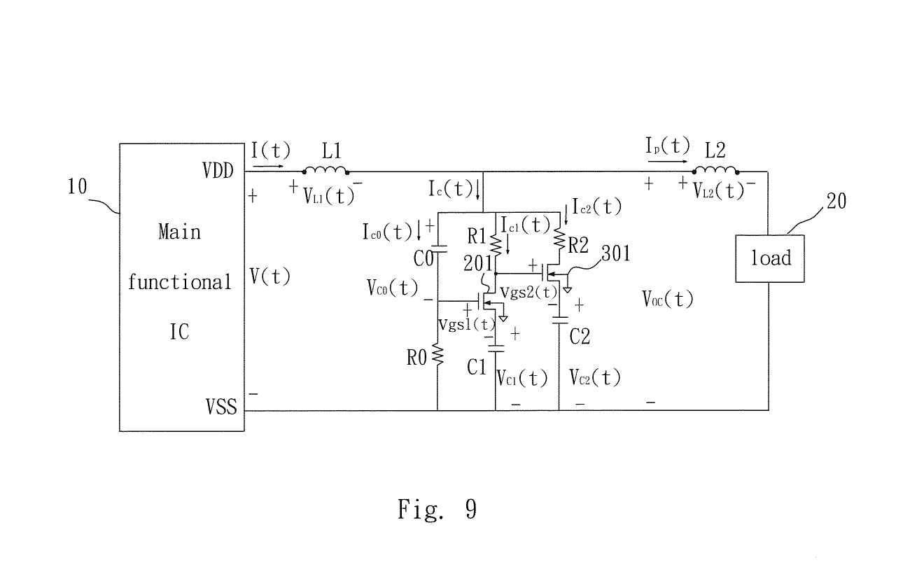

Please refer to FIG. 1 and FIG. 9, which shows a detailed circuit diagram of the power EMI suppression filter according to one embodiment of the present invention. As shown, the reference providing circuit 100 comprises a reference capacitor C0 and a reference resistor R0 connected in series. The primary filtering circuit 200 comprises a first controlling switch 201, which is coupled to a joint node where the reference capacitor C0 and the reference resistor R0 are connected; a first resistor R1, which is connected between the power feeding line VDD and the first controlling switch 201; and a first capacitor C1, which is connected between the first controlling switch 201 and the ground line VSS. The secondary filtering circuit 300 comprises a second controlling switch 301, which is coupled to a joint node where the first resistor R1 and the first controlling switch 201 are connected; a second resistor R2, which is connected between the power feeding line VDD and the second controlling switch 301; and a second capacitor C2, which is connected between the second controlling switch 301 and the ground line VSS. In this embodiment as shown in FIG. 9, the primary filtering circuit 200 comprises one first adjusting circuit 210 (i.e. the first resistor R1) and one second adjusting circuit 220 (i.e. the first capacitor C1). The secondary filtering circuit 300 comprises one third adjusting circuit 310 (i.e. the second resistor R2) and one fourth adjusting circuit 320 (i.e. the second capacitor C2).

According to the embodiment of the present invention, the first controlling switch 201 or the second controlling switch 301 can either be implemented by using a N-type metal oxide semiconductor (NMOS), a P-type metal oxide semiconductor (PMOS) or bipolar junction transistor (BJT). As long as the element is able to receive the first reference signal from the reference providing circuit 100, to receive the second reference signal from the primary filtering circuit 200 and to form a dependent voltage or current curve accordingly, it can be adopted to use as the controlling switch. This embodiment shown in FIG. 9 merely considers a NMOS for an exemplary embodiment but the present invention is apparently not limited thereto.

When considering the first and second controlling switch as a NMOS, agate of the first controlling switch and a gate of the second controlling switch can be respectively connected to any point within the reference providing circuit 100 (for example, to a node where the reference capacitor C0 and the reference resistor R0 are jointed) and to a node where the first resistor R1 and the first controlling switch 201 are jointed in order to receive the reference signal as reference voltages v_{gs1}(t) and v_{gs2}(t) to be its gate bias, respectively. The gate bias should be well controlled so that the NMOS can operate in different regions, for example, a linear region or so-called a non-saturation region, a saturation region, or an active region. At the time, the NMOS may act like a current switch which is voltage-coupled, having its on-current varying with the reference voltage. As such, the present invention employs a voltage-current characteristic of the NMOS to form a non-linear equation. Since the branch currents I_{c0}(t), I_{c1}(t), I_{c2}(t) are dependent based on the voltage-current characteristic of the NMOS, a solution to the quadratic equation will be an intersection of a conic and a straight line. Thus, by properly adjusting the values of those passive elements used in the proposed circuit, the solution can be found. Furthermore, since the output voltage signal V_{oc}(t) is able to define an equation of i₀ and v₀, the proposed primary and secondary filtering circuit of the present invention which are dominated by the NMOS can perform to adjust the values of those passive elements by calculating the voltage/current eigenvalues in order to control and minimize fluctuations of i₀ and v₀. The calculations are processed according to the equations (1) to (17) as below.

$$\begin{matrix}I ( t ) = {I}_{0} + {i}_{0} {e}^{j wt} & ( 1 ) \\ {I}_{c} ( t ) = {i}_{c} {e}^{j ( wl + {φ}_{c} )} & ( 2 ) \\ {V}_{OC} ( t ) = {V}_{0} + {v}_{0} {e}^{j ( wl + {φ}_{0} )} , {φ}_{0} = f ( {i}_{0} , {v}_{0} ) & ( 3 ) \\ {I}_{c} ( t ) = {I}_{c 0} ( t ) + {I}_{c 1} ( t ) + {I}_{c 2} ( t ) & ( 4 ) \\ {I}_{co} ( t ) = C 0 \cdot \frac{d {V}_{C 0} ( t )}{d t} & ( 5 ) \\ {V}_{OC} ( t ) = {V}_{C 0} ( t ) + R 0 \cdot C 0 \cdot \frac{d {V}_{C 0} ( t )}{d t} & ( 6 ) \\ {I}_{c 0} ( t ) = {f}_{0} ( {V}_{OC} , w ) & ( 7 ) \\ {I}_{c 1} ( t ) = C 1 \cdot \frac{d {V}_{C 1} ( t )}{d t} & ( 8 ) \\ {v}_{gs 1} ( t ) = R 0 \cdot C 0 \cdot \frac{d {V}_{C 0} ( t )}{d t} - {V}_{C 1} ( t ) & ( 9 ) \\ {I}_{c 1} ( t ) = \frac{1}{2} {μ}_{n} {C}_{ox} \frac{{W}_{1}}{{L}_{1}} [ 2 ( {v}_{gs 1} - {v}_{DS 1} ) - {v}_{DS 1}^{2} ] & ( 10 ) \\ {V}_{OC} ( t ) = R 1 \cdot C 1 \cdot \frac{d {V}_{C 1} ( t )}{d t} + {v}_{DS 1} ( t ) + {V}_{C 1} ( t ) & ( 11 ) \\ {I}_{c 1} ( t ) = {f}_{1} ( {V}_{OC} , {I}_{co} , w ) & ( 12 ) \\ {I}_{c 2} ( t ) = C 2 \cdot \frac{d {V}_{C 2} ( t )}{d t} & ( 13 ) \\ {v}_{gs 2} ( t ) = {v}_{DS 1} ( t ) + {V}_{C 1} ( t ) & ( 14 ) \\ {I}_{c 2} ( t ) = \frac{1}{2} {μ}_{n} {C}_{ox} \frac{{W}_{2}}{{L}_{2}} [ 2 ( {v}_{gs 2} - {v}_{DS 2} ) - {v}_{DS 2}^{2} ] & ( 15 ) \\ {V}_{oc} ( t ) = R 2 \cdot C 2 \cdot \frac{d {V}_{C 2} ( t )}{d t} + {v}_{DS 2} ( t ) + {V}_{C 2} ( t ) & ( 16 ) \\ {I}_{c 2} ( t ) = {f}_{2} ( {V}_{OC} , {I}_{c 1} , w ) & ( 17 )\end{matrix}$$

In equations (1) to (17), it defines I_{c0}(t), I_{c1}(t), I_{c2}(t) as the values of current that flowing through the reference capacitor C0, the first resistor R1 and the second resistor R2, respectively. V_{C0}(t), V_{C1}(t), V_{C2}(t), V_{L1}(t), V_{L2}(t) are the values of voltage drops across the reference capacitor C0, the first capacitor C1, the second capacitor C2, the inductor L1, and the inductor L2, respectively. μₙ, Cₒₓ, W₁, L₁, W₂, L₂ are relatively known as transistor parameters of the NMOS used for first and second controlling switch. Therefore, by performing a calculation according to the above equations (1) to (17) and I_{c}(t)=f(V_{OC},w) to find a solution to i₀ and v₀ when setting Φ_{c} to be zero, the effective power EMI suppression filter of the present invention is well designed. Practically, the circuit designers nowadays are more likely to use simulation tools such as SPICE to search for an intersection solution to the above equations (1) to (17). When the values of the reference capacitor C0, the reference resistor R0, the first capacitor C1, the first resistor R1, the second capacitor C2 and the second resistor R2 are found such that the phase difference Φ_{c} fits zero, it is indicating that these passive elements used to compose the filter forms a successful power EMI suppression filter that can effectively eliminate interferences and harmonics occurred in the power line at the power source. As a result, the output voltage and the output current of the main functional IC can accordingly process synchronously without any interference involved.

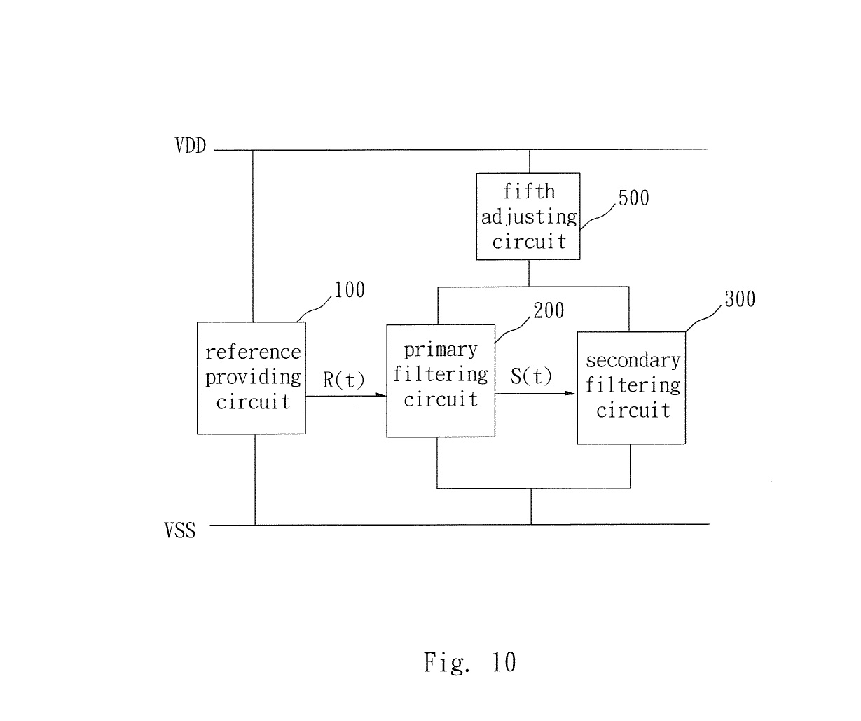

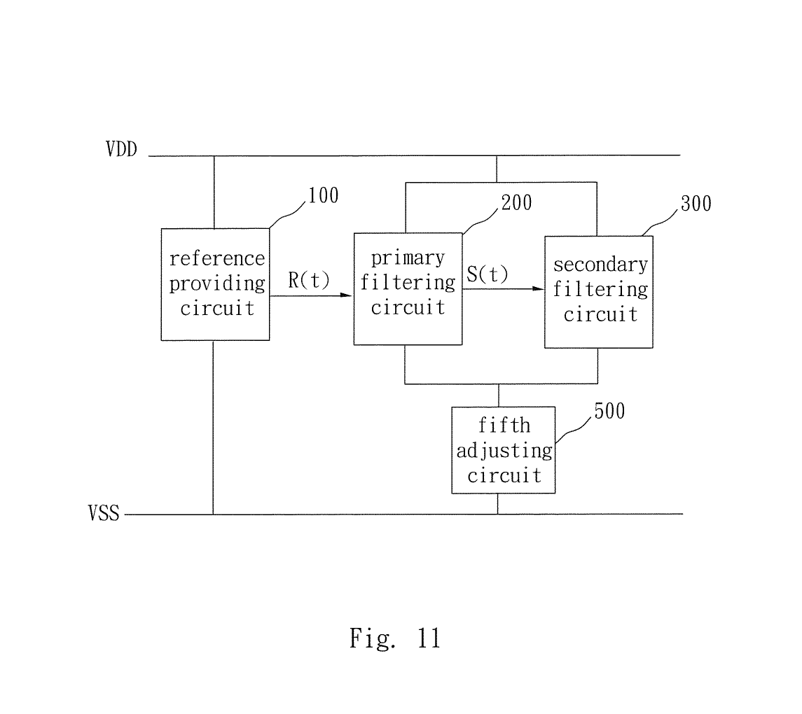

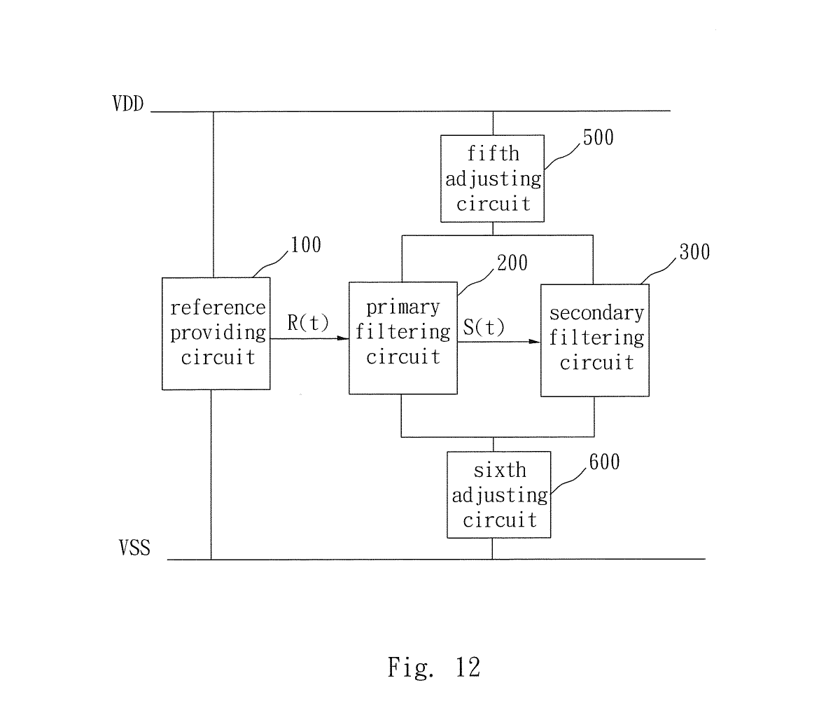

In addition to the reference providing circuit 100, the primary filtering circuit 200 and the secondary filtering circuit 300, the power EMI suppression filter of the present invention may further comprise at least one fifth adjusting circuit 500 and/or at least one sixth adjusting circuit 600, in which the embodiments are shown as FIG. 10 to FIG. 12. In details, FIG. 10 shows an embodiment that the power EMI suppression filter of the present invention further comprises a fifth adjusting circuit 500, and the fifth adjusting circuit 500 is connected between the power feeding line VDD, the primary filtering circuit 200 and the secondary filtering circuit 300. FIG. 11 shows another embodiment that the power EMI suppression filter of the present invention further comprises a fifth adjusting circuit 500 and the fifth adjusting circuit 500 is connected between the primary filtering circuit 200, the secondary filtering circuit 300 and the ground line VSS. As for FIG. 12, it shows yet another embodiment that the power EMI suppression filter of the present invention further comprises both a fifth adjusting circuit 500 and a sixth adjusting circuit 600, wherein the fifth adjusting circuit 500, the primary filtering circuit 200, the secondary filtering circuit 300 and the sixth adjusting circuit 600 are all connected in series between the power feeding line VDD and the ground line VSS.

As a result, with respect to the above mentioned embodiments disclosed by the present invention, it is believed that by optionally disposing the at least one first adjusting circuit, second adjusting circuit, third adjusting circuit, fourth adjusting circuit, fifth adjusting circuit and/or sixth adjusting circuit which are composed of passive elements (for example, resistors, inductor, and/or inductors), when the first and second controlling switch are utilized to provide dependent voltage-current curves based on the reference signals, the calculating of eigenvalues of the output voltage interference and/or the output current interference can be derived. Therefore, a purpose of eliminating the interferences from the power feeding line of the power source is successfully accomplished. As such, when applying the similar sense and methodology, other embodiments of the present invention can also be implemented by the calculation of voltage/current eigenvalues, for example, according to the equations (1) to (17) as shown above. Those skilled in the art can figure their own designs based on the present invention without departing from the scope or spirit of the invention, nevertheless, still falling within the scope of the invention and its equivalent. Therefore, it is obvious that the power EMI suppression filter of the present invention is not only a well designed circuit which effectively eliminates the harmonics frequencies and interferences occurred at the power line but also maintaining great characteristics of both power integrity and signal integrity, thereby being a creative and novel circuit diagram with inventive steps contributed.

As a result, to sum up, the present invention indeed provides a new power EMI suppression filter which has never been seen or proposed ever be fore. By employing the proposed power EMI suppression filter, it is able not only to eliminate the interferences occurred at the power source but also to maintain a complete power integrity, solving the prior issues successfully. Therefore, when compared to the prior arts which only adopts “try and error” methods to layout the EMI filter structure, the present invention apparently shows much more effective performance in both low fabrication cost and low circuit complexity. In addition, the interferences at high frequencies (ranging from 100 MHz to GHz) are almost reduced. Thus, it is believed that the present invention is instinct, effective and highly competitive for IC technology and industries in the market nowadays.

It will be apparent to those skilled in the art that various modifications and variations can be made to the present invention without departing from the scope or spirit of the invention. In view of the fore going, it is intended that the present invention cover modifications and variations of this invention provided they fall within the scope of the invention and its equivalent.

What is claimed is:

1. A power electromagnetic interference suppression filter, which is electrically connected to a power feeding line of a main functional IC and a load, wherein said main functional IC generates an output voltage and an output current after said main functional IC is driven by a power source supplied by said power feeding line; said output voltage is involved with an output voltage interference; said output current is involved with an output current interference; and a phase difference exits between said output voltage interference and said output current interference owing to harmonics interferences generated at said power source, said power electromagnetic interference suppression filter comprising:
a reference providing circuit, electrically coupled to said main functional IC and outputting a first reference signal according to said output voltage interference and/or said output current interference;
a primary filtering circuit, connected to said reference providing circuit in parallel for receiving said first reference signal, wherein said primary filtering circuit calculates eigenvalues of said output voltage interference and/or said output current interference according to said first reference signal and outputs a second reference signal; and
a secondary filtering circuit, connected to said primary filtering circuit for receiving said second reference signal, wherein said secondary filtering circuit accordingly calculates eigenvalues of said output voltage interference and/or said output current interference according to said second reference signal such that said phase difference is adjusted to zero, amplitudes of said output voltage interference and said output current interference are adjusted to zero as well, and an output voltage signal and an output current signal that said load receives are merely direct current (DC) signal without any interferences or harmonics involved.

2. The power electromagnetic interference suppression filter of claim 1, said primary filtering circuit further comprising a first controlling switch and at least one first adjusting circuit, wherein said first controlling switch and said first adjusting circuit are connected in series between said power feeding line and a ground line.

3. The power electromagnetic interference suppression filter of claim 2, wherein said first adjusting circuit is connected between said power feeding line and said first controlling switch, and said first controlling switch is connected to said reference providing circuit for receiving said first reference signal.

4. The power electromagnetic interference suppression filter of claim 3, wherein said primary filtering circuit further comprises a second adjusting circuit, said second adjusting circuit is connected between said first controlling switch and said ground line, and said secondary filtering circuit is connected to either said first adjusting circuit or said second adjusting circuit.

5. The power electromagnetic interference suppression filter of claim 2, wherein said first adjusting circuit is connected between said first controlling switch and said ground line, and said first controlling switch is connected to said reference providing circuit for receiving said first reference signal.

6. The power electromagnetic interference suppression filter of claim 5, wherein said primary filtering circuit further comprises a second adjusting circuit, said second adjusting circuit is connected between said first controlling switch and said power feeding line, and said secondary filtering circuit is connected to either said first adjusting circuit or said second adjusting circuit.

7. The power electromagnetic interference suppression filter of claim 2, wherein said first adjusting circuit is composed of passive elements selected from a group consisting of resistors, inductor and inductors.

8. The power electromagnetic interference suppression filter of claim 4, wherein said second adjusting circuit is composed of passive elements selected from a group consisting of resistors, inductor and inductors.

9. The power electromagnetic interference suppression filter of claim 6, wherein said second adjusting circuit is composed of passive elements selected from a group consisting of resistors, inductor and inductors.

10. The power electromagnetic interference suppression filter of claim 1, wherein said secondary filtering circuit further comprising a second controlling switch and at least one third adjusting circuit, wherein said second controlling switch and said third adjusting circuit are connected in series between said power feeding line and a ground line.

11. The power electromagnetic interference suppression filter of claim 10, wherein said third adjusting circuit is connected between said power feeding line and said second controlling switch, and said second controlling switch is connected to said primary filtering circuit for receiving said second reference signal.

12. The power electromagnetic interference suppression filter of claim 11, wherein said secondary filtering circuit further comprising at least one fourth filtering circuit which is connected between said second controlling switch and said ground line.

13. The power electromagnetic interference suppression filter of claim 10, wherein said third adjusting circuit is connected between said second controlling switch and said ground line, and said second controlling switch is connected to said primary filtering circuit for receiving said second reference signal.

14. The power electromagnetic interference suppression filter of claim 13, wherein said secondary filtering circuit further comprising at least one fourth filtering circuit which is connected between said second controlling switch and said power feeding line.

15. The power electromagnetic interference suppression filter of claim 10, wherein said third adjusting circuit is composed of passive elements selected from a group consisting of resistors, inductor and inductors.

16. The power electromagnetic interference suppression filter of claim 12, wherein said fourth adjusting circuit is composed of passive elements selected from a group consisting of resistors, inductor and inductors.

17. The power electromagnetic interference suppression filter of claim 14, wherein said fourth adjusting circuit is composed of passive elements selected from a group consisting of resistors, inductor and inductors.

18. The power electromagnetic interference suppression filter of claim 2, wherein said first controlling switch is a metal oxide semiconductor or bipolar junction transistor such that a voltage-current characteristic of said metal oxide semiconductor or bipolar junction transistor is adopted for calculating said eigenvalues, and said phase difference between said output voltage interference and said output current interference can be downed to be zero.

19. The power electromagnetic interference suppression filter of claim 10, wherein said second controlling switch is a metal oxide semiconductor or bipolar junction transistor such that a voltage-current characteristic of said metal oxide semiconductor or bipolar junction transistor is adopted for calculating said eigenvalues, and said phase difference between said output voltage interference and said output current interference can be downed to be zero.

20. The power electromagnetic interference suppression filter of claim 1, further comprising at least one fifth adjusting circuit connected in series with said primary filtering circuit and said secondary filtering circuit, such that said at least one fifth adjusting circuit, said primary filtering circuit and said secondary filtering circuit are connected between said power feeding line and a ground line, and said fifth adjusting circuit is composed of passive elements selected from a group consisting of resistors, inductor and inductors.

21. The power electromagnetic interference suppression filter of claim 2, wherein said reference providing circuit comprises a reference resistor and a reference capacitor, said reference resistor and said reference capacitor are connected in series, and said first controlling switch is coupled to a node where said reference resistor and said reference capacitor are jointed.

22. The power electromagnetic interference suppression filter of claim 1, wherein said first reference signal and said second reference signal can be either a voltage signal or a current signal.
